(19) United States
(12) Patent Application Publication
(10) Pub. No.: US 2006/0222183 A1
(43) Pub. Date: Oct. 5, 2006

(54) Audio signal amplifying apparatus and distortion correcting method

(75) Inventors: Hideaki Kushida, Saitama (JP); Hiroshi Saito, Saitama (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Sony Corporation, Shinagawa-ku (JP)

(21) Appl. No.: 11/377,258

(22) Filed: Mar. 17, 2006

(30) Foreign Application Priority Data
Mar. 29, 2005 (JP) 2005-095319

(51) Int. Cl. H03G 3/00

(52) U.S. Cl. 381/61

(57) ABSTRACT

As an embodiment of the present invention, an audio signal is amplified by a power amplifier and an amplified audio signal is generated. By a current detection resistance and a differential amplifier provided between the power amplifier and a speaker, when the amplified audio signal is supplied to the speaker as an output audio signal, the current waveforms of the amplified audio signal on which a distortion component was superimposed by the effect of the speaker and the output audio signal are detected as a current detection signal. A distortion component signal is calculated based on the difference between the current detection signal and the audio signal. And an added result by that the distortion component signal was added to the audio signal by a distortion component adder is supplied to the power amplifier.

### CROSS REFERENCE TO RELATED APPLICATION

The present invention contains subject matter related to Japanese Patent Application JP2005-095319 filed in the Japanese Patent Office on Mar. 29, 2005, the entire contents of which being incorporated herein by reference.

### BACKGROUND OF THE INVENTION

### Field of the Invention

The present invention relates to an audio signal amplifying apparatus and a distortion correcting method, and is applicable, for example, to an audio apparatus that amplifies an audio signal supplied from the outside and transmits the amplified signal to an external speaker.

### DESCRIPTION OF THE RELATED ART

An audio apparatus that amplifies an audio signal supplied from an external Compact Disc (CD) player or the like and transmits the amplified signal to an external speaker, to emit a sound according to the audio signal from the speaker has been widely used.

Here, generally, in a speaker, an amplified audio signal supplied from an audio apparatus, that is, an electric signal flows to a voice coil, so that magnetic force is generated and a diaphragm is vibrated. However, by the general properties of a coil, when the electric signal flows to the voice coil, counter electromotive force arises.

Therefore, in an audio apparatus, there has been a problem that distortion is generated in an amplified audio signal supplied to the speaker by the counter electromotive force from the speaker, and the quality of a sound emitted from the speaker is deteriorated.

Thus, in an audio apparatus, a low-distortion speaker apparatus in that a negative feedback system to reduce a distortion component in a current waveform flown to the voice coil of a speaker is adopted has been proposed (for example, see Jpn. Pat. Appln. Laid-Open No. 1987-120195 [FIG. 4, page 1-2]).

### SUMMARY OF THE INVENTION

However, in an audio apparatus having such configuration, a resistance for current detection is connected between a ground and a speaker. Therefore, noise sneaks from a power supply circuit or the like in the audio apparatus, and a so-called regenerative current sometimes flows to the resistance for current detection.

In this case, in the audio apparatus, only the current flown to the speaker cannot be correctly detected by the effect of the regenerative current. Therefore, a distortion component by the counter electromotive force cannot be correctly extracted, and distortion by the counter electromotive force cannot be completely eliminated. There has been a problem that the quality of a sound emitted from the speaker is deteriorated.

In view of the foregoing, it is desirable to provide an audio signal amplifying apparatus and a distortion correcting method in that the quality of sounds emitted from a speaker can be improved.

According to an embodiment of the present invention, an audio signal is amplified by an amplifier and an amplified audio signal is generated. Before the audio signal amplified by the amplifier is supplied to a speaker, the current waveform of the audio signal on which a distortion component was superimposed by the effect of the speaker is detected. The distortion component is calculated based on the difference between the current waveform and the signal waveform of the audio signal. And an added result by that the distortion component was added to the audio signal is supplied to the amplifier.

Thereby, only the distortion component which was superimposed on the amplified audio signal by the effect of the speaker can be correctly calculated without receiving the effect of noise sneak, and the distortion component generated by the effect of the speaker and the distortion component added to the audio signal can be canceled out. Thus, sounds faithfully according to the audio signal can be emitted from the speaker.

Further, according to an embodiment of the present invention, it is an audio signal amplifying apparatus for transmitting plural amplified audio signals by that audio signals on plural channels were amplified respectively, to a speaker of each channel via a ground wire used in common by each of the channels respectively. And an amplifier for amplifying the audio signal for every channel and generating the amplified audio signal, a current detecting section provided between the amplifier and a speaker of each channel, for respectively detecting the current waveforms of the amplified audio signals on which a distortion component was superimposed by the effect of the speaker and the effect from other channel via the ground wire when the amplified audio signals were transmitted from the amplifier to the speaker, a distortion component calculating section for calculating the distortion component based on the difference between the current waveform and the signal waveform of the audio signal for every channel, and a distortion component adding section for supplying an added result by that the distortion component was added to the audio signal for every channel to the amplifier are provided.

Thereby, only the distortion component which was superimposed on the amplified audio signal by the effect of the speaker and the effect from other channel via the ground wire can be correctly calculated, and the distortion component generated by the effect of the speaker and the effect from other channel and the distortion component previously added to the audio signal can be canceled out. Thus, sounds faithfully according to the audio signal can be emitted from the speaker.

The nature, principle and utility of the present invention will become more apparent from the following detailed description when read in conjunction with the accompanying drawings in which like parts are designated by like reference numerals or characters.

### BRIEF DESCRIPTION OF THE DRAWINGS

In the accompanying drawings:

FIG. 1 is a schematic circuit diagram showing the configuration of an audio apparatus according to a first embodiment;

FIG. 2 is a schematic sectional view showing the configuration of a speaker;

FIG. 3 is a schematic diagram showing the impedance characteristic of the speaker;

FIGS. 4A to 4F are schematic waveform charts showing signal waveforms;

FIGS. 5A and 5B are schematic waveform charts showing the frequency characteristics in the case without distortion correction;

FIGS. 6A and 6B are schematic waveform charts showing the frequency characteristics in the case with distortion correction;

FIG. 7 is a schematic waveform chart showing the characteristics of a distortion factor in the first embodiment;

FIGS. 8A and 8B are schematic circuit diagrams for explaining the effect of a regenerative current from other circuit;

FIGS. 9A and 9B are schematic circuit diagrams for explaining the effect of disturbance;

FIG. 10 is a schematic circuit diagram showing the configuration of an audio apparatus according to a second embodiment;

FIGS. 11A and 11B are schematic circuit diagrams for explaining the effect of a leakage current from other channel;

FIG. 12 is a schematic waveform chart showing channel separation characteristics;

FIG. 13 is a schematic waveform chart showing the characteristics of a distortion factor in the second embodiment; and

FIGS. 14A and 14B are schematic circuit diagrams for explaining the connecting part of a current detection resistance.

### DETAILED DESCRIPTION OF THE EMBODIMENTS

Preferred embodiments of the present invention will be described with reference to the accompanying drawings:

### (1) First Embodiment

(1-1) Configuration of Audio Apparatus

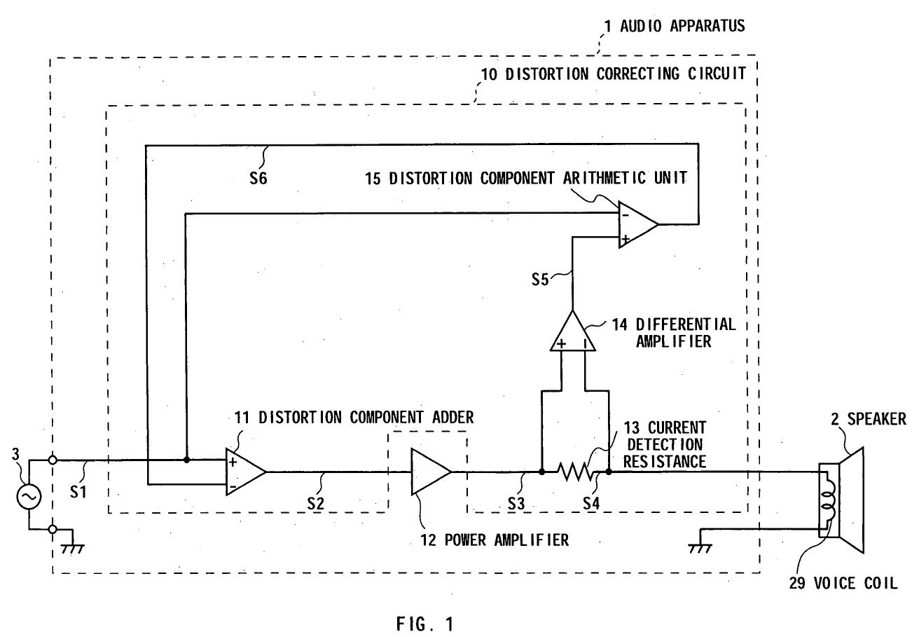

Referring to FIG. 1, an audio apparatus 1 according to a first embodiment operates as a so-called audio amplifier that amplifies an audio signal S1 supplied from an audio signal source 3 such as a Compact Disc (CD) player, and supplies the amplified signal to a speaker 2. Thereby, a sound according to the audio signal S1 is emitted from the speaker 2.

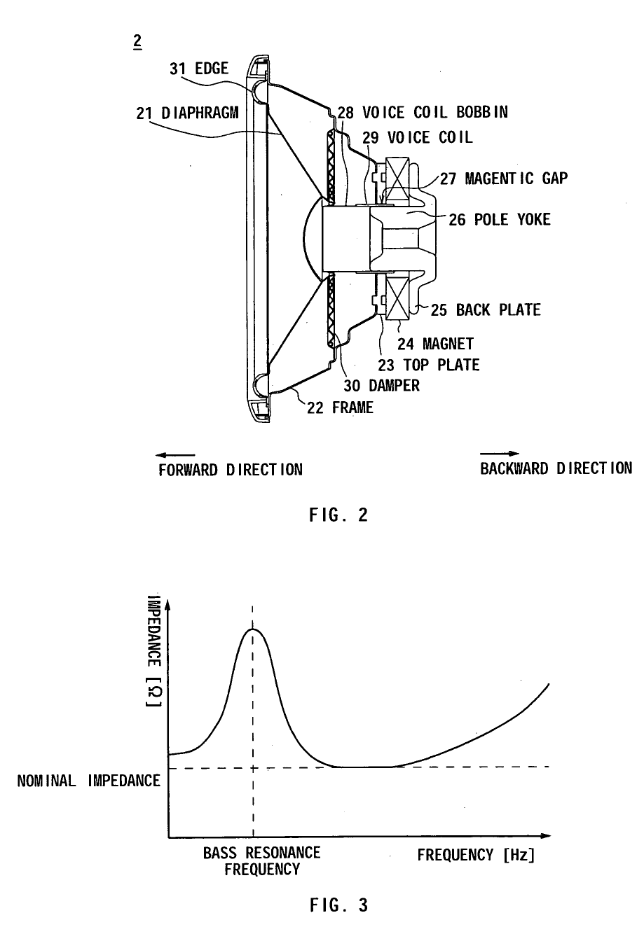

Here, as shown in FIG. 2 of a sectional view, the speaker 2 has a conic diaphragm 21. The diaphragm 21 is fixed in the front outer circumference part of a frame 22 in an almost mortar shape, via an edge 31 made of resin material having bendability. The diaphragm 21 can be freely moved (vibrated) in the forward and backward directions to the frame 22.

In the frame 22, a top plate 23, a magnet 24 and a back plate 25 that are respectively in an almost disc shape are fixed to the back side, and a pole yoke 26 is provided so as to protrude from the center part of the back plate 25 to the forward direction. A magnetic circuit is formed by that the pole yoke 26 penetrates the magnet 24, and a magnetic gap 27 is formed between the magnet 24 and the top plate 23.

A voice coil bobbin 28 is made from an almost cylindrical metallic material, and is coaxially supported by a damper 30 and is fixed to the back center part of the diaphragm 21. The voice coil 29 is coiled up so as to be positioned in the magnetic gap 27. The voice coil 29 is connected to a connecting terminal (not shown) fixed to the frame 22 via a lead wire (not shown), and an output audio signal S4 having an alternative waveform is supplied from the audio apparatus 1.

That is, in the speaker 2, a current according to an output audio signal S4 from the audio apparatus 1 flows to the voice coil 29, so that electromagnetic force according to the current of the output audio signal S4 is generated. At this time, in the speaker 2, the diaphragm 21, the voice coil bobbin 28 and the voice coil 29 are vibrated in one body by the electromagnetic force, in the forward and backward directions to other parts such as the frame 22. A sound according to the output audio signal S4 can be produced by vibrating the surrounding air.

By the way, in the speaker 2, as shown in FIG. 3, an impedance changes according to a frequency, by the properties of the voice coil 29. An impedance takes the maximal value at a low resonance frequency. If the frequency rises from the low resonance frequency, the impedance reduces and takes the minimal value, that is, a nominal impedance. As the frequency further rises, the impedance gradually increases.

Furthermore, in the speaker 2, when the output audio signal S4 flows to the voice coil 29, counter electromotive force is generated in the voice coil 29 by the general properties of a coil. The current waveform of the output audio signal S4 is distorted by the counter electromotive force, and the quality of an emitted sound is deteriorated.

Thus, in the audio apparatus 1 (FIG. 1), the audio signal Si is amplified by a power amplifier 12, and distortion by the effect of the voice coil 29 of the speaker 2 is corrected by a distortion correcting circuit 10.

The distortion correcting circuit 10 first subtracts a distortion component signal S6 (the details will be described later) from the audio signal S1 by a distortion component adder 11 to generate an add audio signal S2, and supplies this to the power amplifier 12.

The power amplifier 12 amplifies the add audio signal S2 by a predetermined amplification factor to generate an amplified audio signal S3, and supplies the amplified audio signal S3 to a current detection resistance 13 in the distortion correcting circuit 10.

The current detection resistance 13 is a non-inductive resistance that almost does not have a reactance component. The current detection resistance 13 slightly attenuates the amplified audio signal S3 supplied from the power amplifier 12, and transmits the attenuated signal to the speaker 2 as the output audio signal S4. At this time, in the current detection resistance 13, a potential difference is caused between the amplified audio signal S3 and the output audio signal S4, so that the size of a current value in the amplified audio signal S3 and the output audio signal S4 can be detected based on the potential difference. Note that, since the current detection resistance 13 is a non-inductive resistance, the potential difference between the both ends is only relative to the size of the current flown to the current detection resistance 13.

In this connection, in the current detection resistance 13, a comparatively small resistance value such as 0.1 Ω degree is selected, so that a power loss of the amplified audio signal S3 by the current detection resistance 13 is restrained at the minimum.

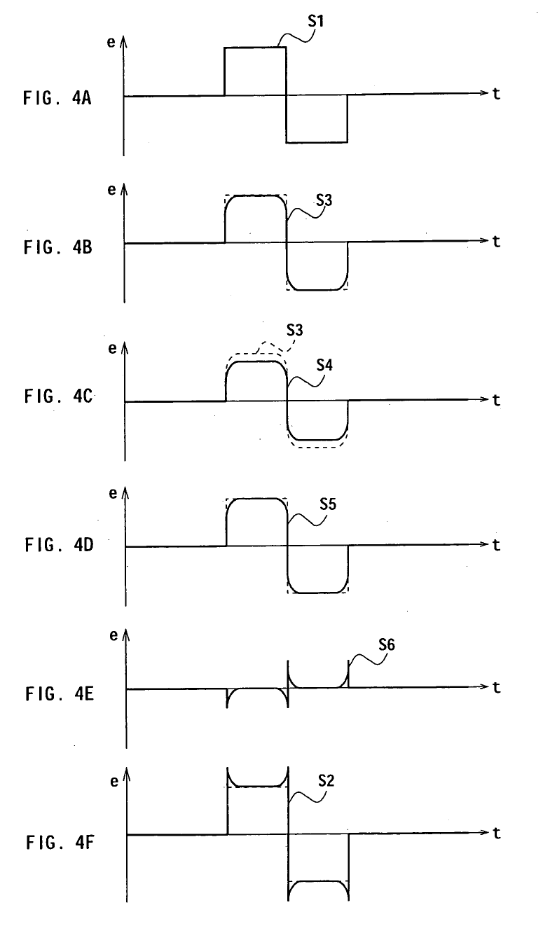

Here, because the distortion component signal S6 is “0” in the initial state, the add audio signal S2 becomes an almost same waveform as the audio signal S1. However, the amplified audio signal S3 and the output audio signal S4 become distorted waveforms by the effect of the aforementioned counter electromotive force generated in the voice coil 29 of the speaker 2. Practically, for example, when the audio signal S1 is a square wave as shown in FIG. 4A, the amplified audio signal S3 and the output audio signal S4 become distorted waveforms to the audio signal S1 (FIG. 4A) as shown in FIGS. 4B and 4C.

The amplified audio signal S3 and the output audio signal S4 are supplied to the differential amplifier 14. The differential amplifier 14 calculates the difference between the amplified audio signal S3 and the output audio signal S4 to amplify them by a predetermined amplification factor, and generates a current detection signal S5 (FIG. 4D) that shows a current waveform flown to the current detection resistance 13 (that is, the current waveform in the amplified audio signal S3 and the output audio signal S4), and transmits this to the distortion component arithmetic unit 15.

In this connection, the differential amplifier 14 amplifies so that the signal level of the current detection signal S5 becomes almost equivalent to the signal level of the audio signal S1.

The distortion component arithmetic unit 15 calculates the difference between the current detection signal S5 and the original audio signal S1 that does not include a distortion component, to extract only the distortion component included in the amplified audio signal S3 and the output audio signal S4, and transmits this to the distortion component adder 11 as a distortion component signal S6 (FIG. 4E).

Here, the distortion component signal S6 corresponds to the signal by that only the distortion component generated by the counter electromotive force from the speaker 2 was extracted. That is, the distortion correcting circuit 10 detects the distortion component included in the output audio signal S4, based on the potential difference between the amplified audio signal S3 and the output audio signal S4.

The distortion component adder 11 deducts the distortion component signal S6 from the original audio signal S1 that does not include a distortion component as described above. That is, the distortion component adder 11 inverts the phase of the distortion component signal S6 and adds this to the audio signal S1 to generate an add audio signal S2 in that the distortion component is added in the inverted phase (FIG. 4F), and transmits this to the power amplifier 12.

Responding to this, the power amplifier 12 amplifies the add audio signal S2 in that the distortion component is added in the inverted phase as it is, to generate an amplified audio signal S3, and transmits the output audio signal S4 to the speaker 2 via the current detection resistance 13.

At this time, in the amplified audio signal S3 and the output audio signal S4, although the waveform is distorted by the counter electromotive force generated in the voice coil 29 of the speaker 2 as described above, the distortion component by the counter electromotive force is canceled out by the distortion component signal S6 having the inverted phase that was previously added. Therefore, the amplified audio signal S3 and the output audio signal S4 do not almost include a distortion component, and are corrected to waveforms almost equivalent to the original audio signal S1.

In this manner, in the audio apparatus 1, negative current feedback is performed via the system of the current detection resistance 13, the differential amplifier 14, the distortion component arithmetic unit 15 and the distortion component adder 11. Thereby, the output audio signal S4 which was corrected to the waveform almost equivalent to the original audio signal S1 can be supplied to the voice coil 29 of the speaker 2, irrespective of the effect of the counter electromotive force from the voice coil 29. Thus, a high quality sound based on the audio signal S1 can be faithfully emitted from the speaker 2.

(1-2) Operation and Effect

According to the above configuration, in the distortion correcting circuit 10 in the audio apparatus 1, the current detection resistance 13 is provided between the power amplifier 12 and the speaker 2. The distortion correcting circuit 10 detects the current waveform of an output audio signal S4 to be supplied to the speaker 2 as a current detection signal S5 by the current detection resistance 13 and the differential amplifier 14, and calculates the difference between the current detection signal S5 and the audio signal S1 to extract a distortion component signal S6, and adds the distortion component signal S6 to the original audio signal S1 in the inverted phase.

As a result, negative current feedback is performed on the audio signal S1 by the distortion correcting circuit 10, so that the distortion component of the output audio signal S4 by counter electromotive force generated in the voice coil 29 of the speaker 2 can be canceled out. Therefore, the distortion correcting circuit 10 can supply the output audio signal S4 not including a distortion component to the speaker 2.

The current of the output audio signal S4 being the almost same signal waveform as the original audio signal S1 not including the distortion component is supplied to the voice coil 29. Therefore, the speaker 2 can emit a sound faithfully according to the original audio signal S1.

Note that, the distortion correcting circuit 10 performs negative current feedback on the audio signal S1. Therefore, even if any distortion is generated in the output audio signal S4, or even if distortion does not occur, the output audio signal S4 can be corrected faithfully in accordance with the signal waveform of the original audio signal S1.

Moreover, the distortion correcting circuit 10 always performs negative current feedback on the audio signal S1. Therefore, whenever any distortion is generated in the output audio signal S4, correction can be immediately performed on the audio signal S1 in consideration of the distortion component. Thus, high quality sounds can be emitted from the speaker 2 at all times.

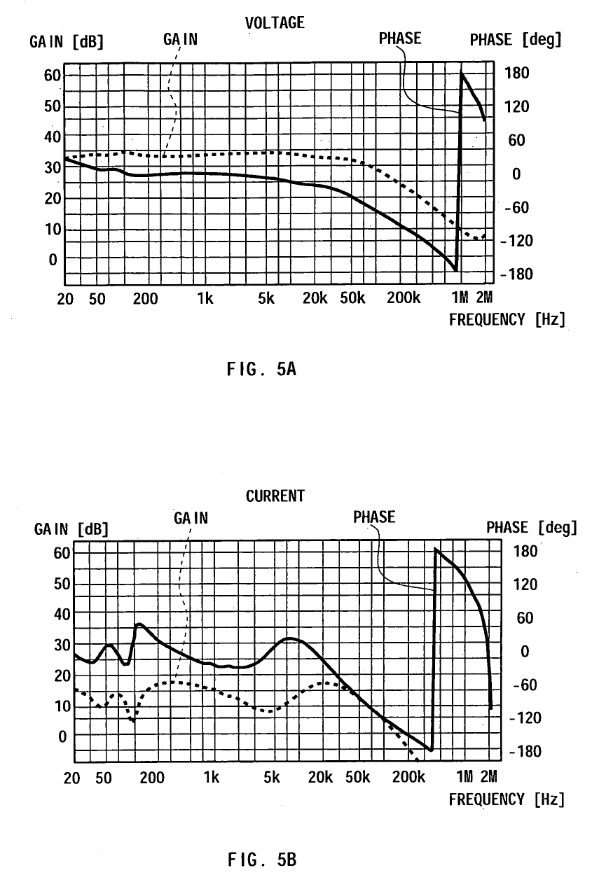

Here, the frequency characteristics of the voltage and the current in a conventional audio apparatus (not shown) only using the power amplifier 12 without using the distortion correcting circuit 10 are shown in FIGS. 5A and 5B. In the conventional audio apparatus, in an audio band (approximately 20 Hz-20 kHz), although as to the voltage, the gain and the phase are almost flat and show fine characteristics (FIG. 5A), as to the current, the gain and the phase widely vary depending on the frequency (FIG. 5B). In this case, the speaker 2 generates electromagnetic force relative to the current flown to the voice coil 29. Therefore, the frequency characteristic of a sound to be emitted in accordance with the frequency characteristic of the current is deteriorated; thus, the sound quality is lowered.

On the contrary, the distortion correcting circuit 10 in the audio apparatus 1 according to the first embodiment of the present invention detects the current waveform actually flown to the speaker 2 by the current detection resistance 13 and the differential amplifier 14 as a current detection signal S5, and corrects the signal waveform of the output audio signal S4 by matching to the input audio signal S1 by negative current feedback based on the current detection signal S5.

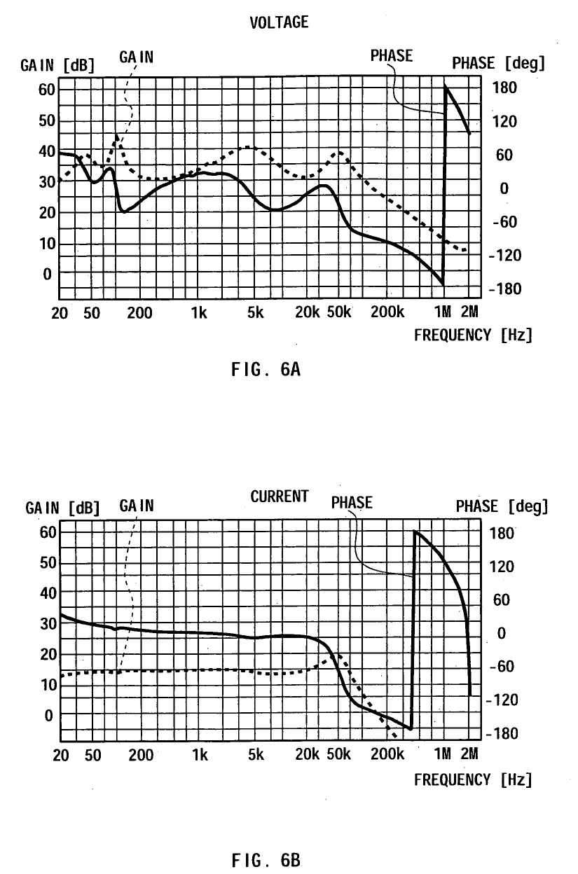

As a result, in the audio apparatus 1 of the first embodiment of the present invention, as shown in FIGS. 6A and 6B, although as to the voltage, the characteristics of the gain and the phase are disturbed (FIG. 6A), as to the current, the characteristics of the gain and the phase in the audio band become almost flat; thus, it becomes fine frequency characteristics (FIG. 6B). Therefore, in the audio apparatus 1, a fine quality sound can be emitted from the speaker 2.

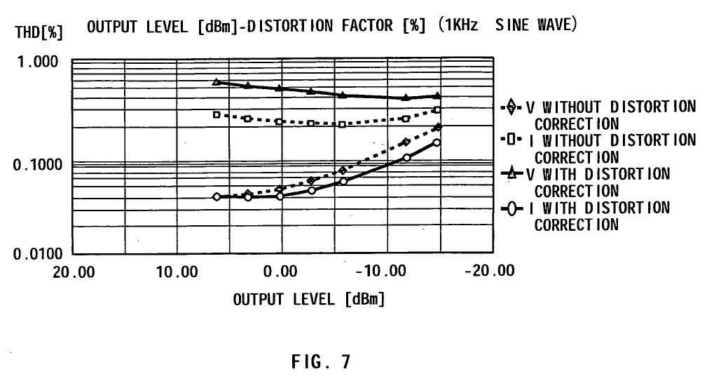

Further, as shown in FIG. 7, compared the characteristic of the distortion factors of the voltage (V) and the current (I) in the case where the distortion component was corrected by the distortion correcting circuit 10 in the audio apparatus 1 of the first embodiment of the present invention with the case where the distortion component was not corrected in the conventional audio apparatus, in the audio apparatus 1, although the Total Harmonic Distortion (THD) (hereinafter, THD is simply referred to as a distortion factor) of the voltage (V) increases (that is, deteriorates) by the distortion correcting circuit 10, the distortion factor of the current (I) decreases and is improved. That is, in the audio apparatus 1, the frequency characteristic of sounds emitted from the speaker 2 is improved, and the sound quality can be remarkably improved.

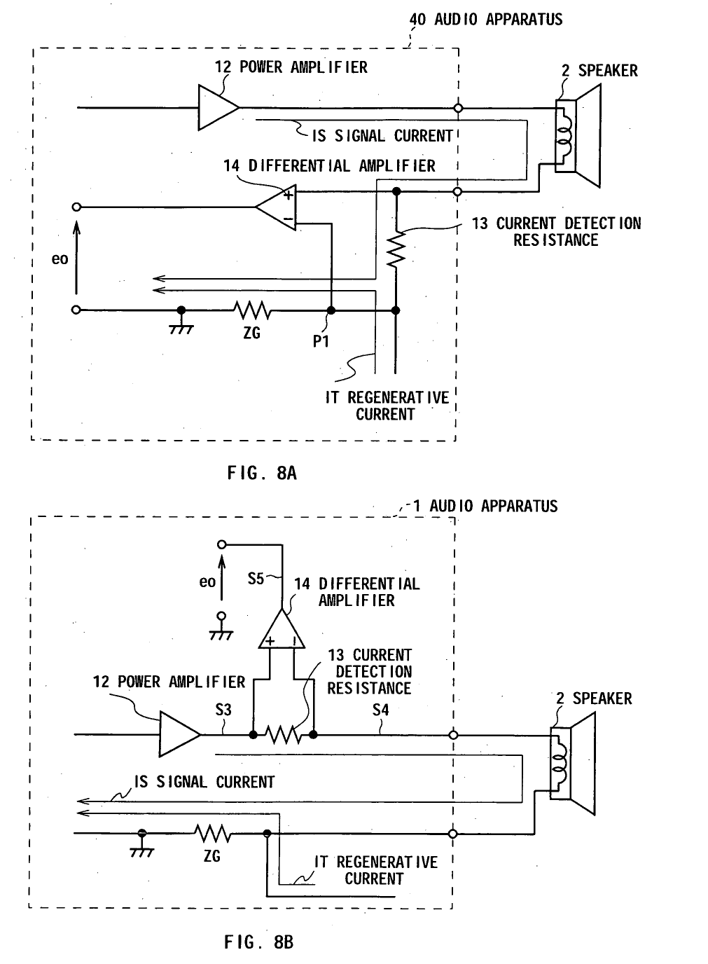

On the other hand, assuming the case where a regenerative current IT is generated via a ground by the effect of a current from other circuit such as a power supply circuit, for example, in the case of an audio apparatus 40 in that a current detection resistance 13 is connected to the ground side as shown in FIG. 8A, although current feedback is performed via a distortion component adder (not shown), a potential in a point P1 varies by an impedance ZG on the ground wire by the effect of the regenerative current IT from other circuit (not shown), and a voltage eo has the effect of the regenerative current IT.

At this time, in the audio apparatus 40, the voltage eo is different from the potential difference at the both ends of the current detection resistance 13. Therefore, a distortion component by counter electromotive force generated in the voice coil 29 of the speaker 2 cannot be correctly calculated. Thus, the distortion of the signal current IS flown to the speaker 2 cannot be properly corrected.

On the contrary, in the audio apparatus 1 of the first embodiment of the present invention, as shown in FIG. 8B, since the current detection resistance 13 is connected between the power amplifier 12 and the speaker 2 (that is, at the signal line side), the voltage eo showing the potential of the current detection signal S5 does not have the effect of the regenerative current IT.

Therefore, the audio apparatus 1 can correctly detect the potential difference between the both ends of the current detection resistance 13 by the current detection signal S5. Thus, the distortion component is calculated with high accuracy without receiving the effect of the regenerative current IT, and the distortion generated in the output audio signal S4 can be properly corrected.

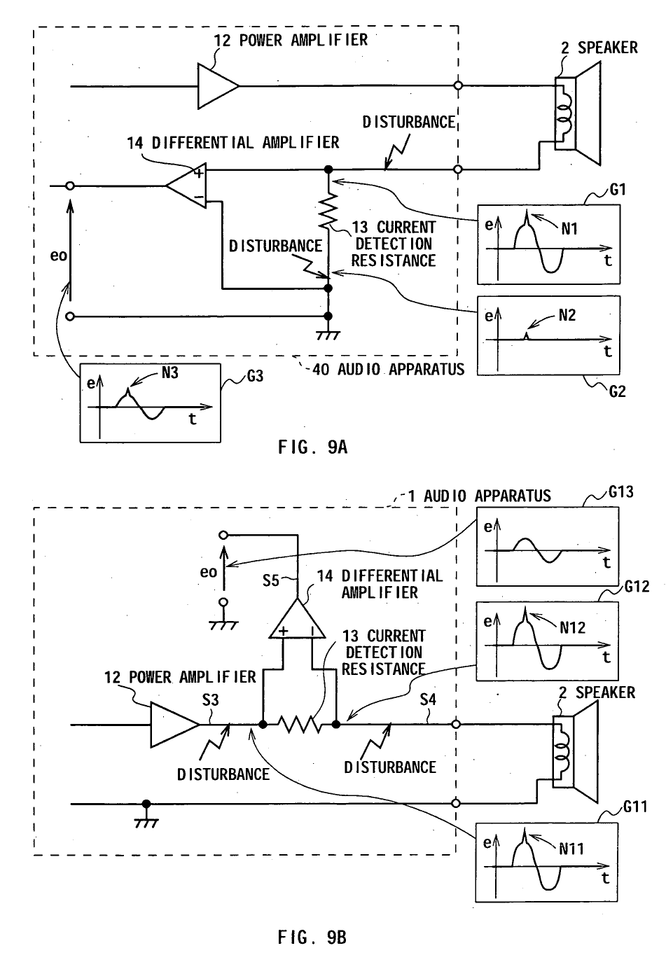

Further, assuming the case of receiving the effect of disturbance at the both ends of the current detection resistance 13 by electromagnetic waves or the like, for example, as shown in FIG. 9A, in the case of the audio apparatus 40, as signal waveforms G1 and G2 at the both ends of the current detection resistance 13, disturbance noise components N1 and N2 on the same level are respectively superimposed on the audio signal by the disturbance.

In this case, in the audio apparatus 40, because an impedance at the ground side is low, the noise component N2 of the audio signal becomes smaller than the noise component N1. Therefore, as a signal waveform G3, a noise component N3 being the difference between the noise components N1 and N2 is superimposed on the voltage eo when the difference was calculated by the differential amplifier 14; thus, the potential difference between the both ends of the current detection resistance 13 cannot be correctly detected.

On the contrary, in the audio apparatus 1 of an embodiment of the present invention, as shown in FIG. 9B, when it received the effect of disturbance at the both ends of the current detection resistance 13, impedances at the both ends of the current detection resistance 13 are almost equal. Therefore, as signal waveforms G11 and G12, the size of noise components N11 and N12 superimposed on the amplified audio signal S3 and the output audio signal S4 flown to the both ends of the current detection resistance 13 respectively becomes almost equal.

For that reason, in the audio apparatus 1, as shown in a signal waveform G13, a noise component is almost not superimposed as the voltage eo, when the difference is calculated by the differential amplifier 14. As a result, in the audio apparatus 1, the potential difference between the both ends of the current detection resistance 13 can be correctly detected, and the distortion component is calculated with high accuracy. Thus, distortion generated in the output audio signal S4 can be properly corrected.

Moreover, in the audio apparatus 1, even if a cable connecting the audio apparatus 1 and the speaker 2 received the effect of disturbance or the like and noise was superimposed on the output audio signal S4, only a distortion component different from the original audio signal S1 is extracted by the distortion correcting circuit 10, and the distortion component generated in the output audio signal S4 can be corrected. Thus, a sound by that the audio signal S1 was faithfully reproduced can be emitted from the speaker 2, irrespective of the effect of the disturbance.

According to the above configuration, in the distortion correcting circuit 10 of the audio apparatus 1, the current detection resistance 13 is provided between the power amplifier 12 and the speaker 2. A distortion component is calculated by the current detection resistance 13 and the differential amplifier 14, and it is added to the original audio signal S1 in the inverted phase. Thereby, distortion in the output audio signal S4 generated by counter electromotive force occurred in the voice coil 29 of the speaker 2 is cancelled out, and the output audio signal S4 can be corrected to the signal waveform equivalent to the input audio signal S1 having no distortion. Thus, the sound quality of the speaker 2 can be remarkably improved.

### (2) Second Embodiment

(2-1) Configuration of Audio Apparatus

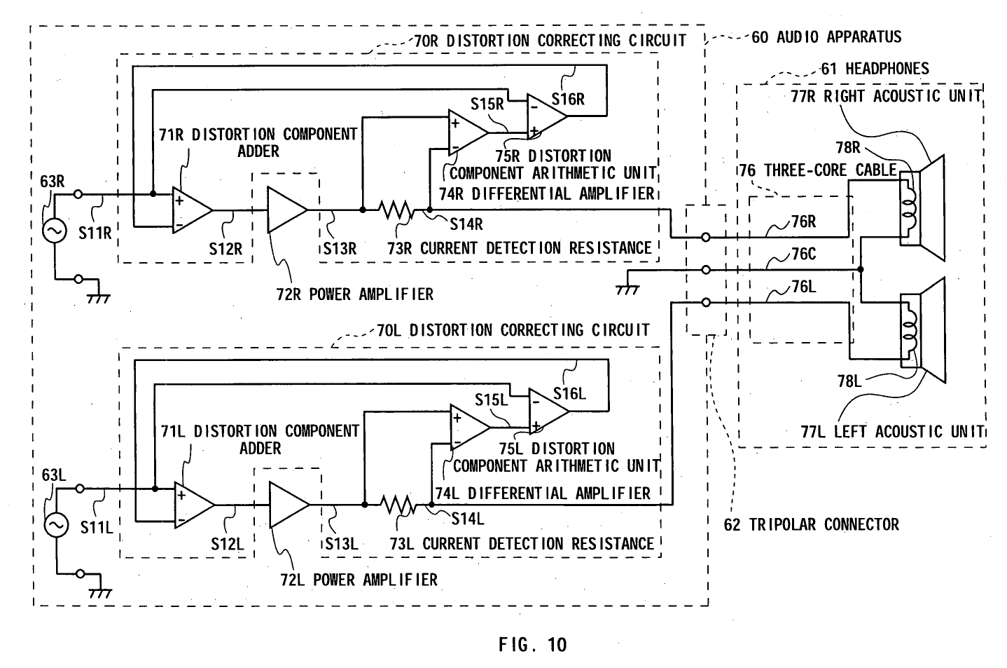

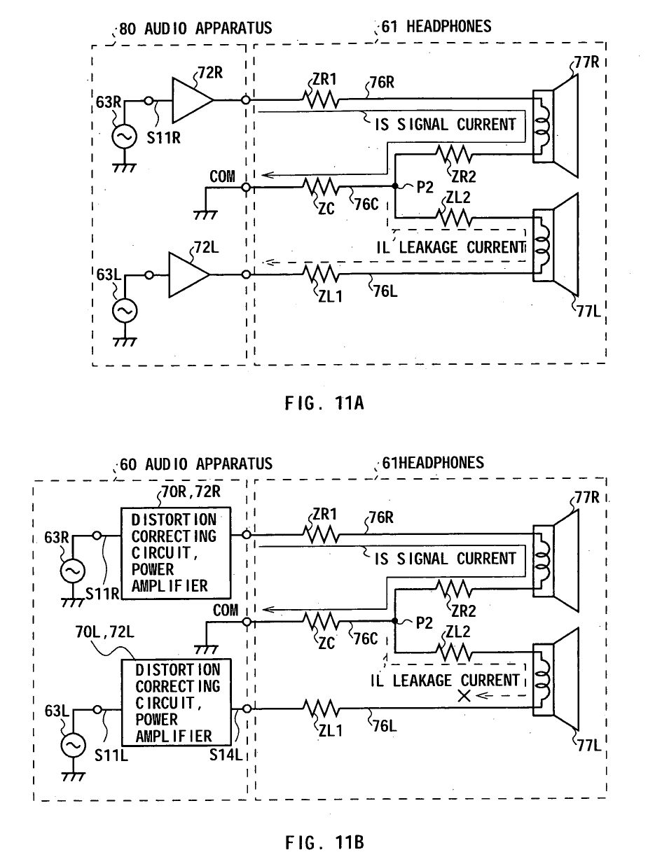

Referring to FIG. 10 in that the same reference numerals are added to corresponding parts in FIG. 1, an audio apparatus 60 according to a second embodiment is for example a portable Compact Disc (CD) player. The audio apparatus 60 amplifies audio signals S11R and S11L on the two channels of left and right supplied from audio signal sources 63R and 63L that form a CD reproducing section by power amplifiers 72R and 72L respectively, and transmits the amplified signals to headphones 61 via a tripolar connector 62. Thereby, the left and the right sounds are emitted from a right acoustic unit 77R and a left acoustic unit 77L in the headphones 61 respectively.

Compared with the audio apparatus 1 (FIG. 1), the audio apparatus 60 has a common configuration, other than the respect that has distortion correcting circuits 70R and 70L for two channels of left and right corresponding to the distortion correcting circuit 10, and the respect that the right acoustic unit 77R and the left acoustic unit 77L in the headphones 61 corresponding to the speaker 2 are connected by a three-core cable 76 using a ground wire 76C in common.

Here, the three-core cable 76 connects the distortion correcting circuit 70R and the right acoustic unit 77R by a right signal line 76R, and connects the distortion correcting circuit 70L and the left acoustic unit 77L by a left signal line 76L, and also the ground wire 76C is used in common by the right signal line 76R and the left signal line 76L.

The distortion correcting circuit 70R (the right (R) channel) in the audio apparatus 60 deducts a distortion component signal S16R from an audio signal S11R by a distortion component adder 71 to generate an add audio signal S12R, and supplies this to a power amplifier 72R, similarly to the aforementioned distortion correcting circuit 10R in the audio apparatus 1 (FIG. 1).

The power amplifier 72R amplifies the add audio signal S12R to generate an amplified audio signal S13R similarly to the power amplifier 12 (FIG. 1), and supplies this to a current detection resistance 73R.

The current detection resistance 73R is a non-inductive resistance. The current detection resistance 73R slightly attenuates the amplified audio signal S3 supplied from the power amplifier 72R to generate an output audio signal S14R, and supplies this to the right acoustic unit 77R via a tripolar connector 62 and the three-core cable 76 of the headphones 61.

At this time, the distortion correcting circuit 70R detects the current waveform of an output audio signal S14R to be transmitted to the right acoustic unit 77R by the current detection resistance 73R and the differential amplifier 74R as a current detection signal S15R, calculates the difference between the current detection signal S15R and the audio signal S11R to extract a distortion component signal S16R, and adds the distortion component signal S16R to the original audio signal S11R in the inverted phase by the distortion component adder 71R.

Thereby, in the audio apparatus 60, distortion in the output audio signal S14R by counter electromotive force generated in the voice coil 78R of the right acoustic unit 77R can be previously corrected by the distortion correcting circuit 70R. Therefore, the output audio signal S14R that was corrected to the signal waveform almost equivalent to the original audio signal S11R can be flown to the voice coil 78R of the right acoustic unit 77R. Thus, a sound faithfully according to the audio signal S11R can be emitted from the right acoustic unit 77R.

Note that, with respect to the distortion correcting circuit 70L (the left (L) channel) in the audio apparatus 60, an output audio signal S14L which was corrected to the signal waveform almost equivalent to the original audio signal S11L can be flown to the voice coil 78L of the left acoustic unit 77L, similarly to the distortion correcting circuit 70R (the right channel). Thus, a sound faithfully according to the audio signal S11L can be emitted from the left acoustic unit 77L.

(2-2) Operation and Effect

According to the above configuration, in the distortion correcting circuits 70R and 70L in the audio apparatus 60 (FIG. 10), similarly to the distortion correcting circuit 10 in the audio apparatus 1 (FIG. 1) according to the first embodiment, the current detection resistances 73R and 73L are provided between the power amplifiers 72R and 72L and the right acoustic unit 77R and the left acoustic unit 77L respectively. The distortion correcting circuits 70R and 70L detect the current waveforms of output audio signals S14R and S14L to be supplied to the right acoustic unit 77R and the left acoustic unit 77L by the current detection resistances 73R and 73L and the differential amplifiers 74R and 74L as current detection signals S15R and S15L respectively, calculate the differences between the current detection signals S15R and S15L and the audio signals S11R and S11L to extract distortion component signals S16R and S16L, and add the distortion component signals S16R and S16L to the original audio signals S11R and S11L in the inverted phase respectively. Thereby, so-called negative current feedback is performed.

Thereby, negative feedback is performed on the audio signals S11R and S11L by the distortion correcting circuits 70R and 70L respectively, so that distortion in the output audio signals S14R and S14L by counter electromotive force generated in the voice coil 78R of the right acoustic unit 77R and the voice coil 78L of the left acoustic unit 77L respectively can be canceled out. Thus, the output audio signals S14R and S14L in which a distortion component is not almost included can be supplied to the right acoustic unit 77R and the left acoustic unit 77L.

In the right acoustic unit 77R and the left acoustic unit 77L, the output audio signals S14R and S14L being the signal waveforms almost equivalent to the original audio signals S11R and S11L not including a distortion component are supplied to the voice coils 78R and 78L respectively. Therefore, high quality sounds faithfully according to the original audio signals S11R and S11L can be emitted.

Furthermore, the distortion correcting circuits 70R and 70L perform negative current feedback on the audio signals S11R and S11L respectively, similarly to the distortion correcting circuit 10. Therefore, even if any distortion is generated in the output audio signals S11R and S11L, or even if distortion does not occur, the output audio signals S14R and S14L can be supplied to the right acoustic unit 77R and the left acoustic unit 77L in the state where their signal waveforms are equivalent to the original audio signals S11R and S11L respectively.

Furthermore, the effect of a leakage current to other channel caused by that the ground wire 76C has been used in common will be considered. In an audio apparatus 80 that has only power amplifiers 72R and 72L and in that a distortion component is not corrected as shown in FIG. 11A, for example, when an audio signal S11R was supplied from an audio signal source 63R only to the right channel, a ground wire 76C has an impedance ZC and a potential at the branch point P2 of the ground wire 76C is not to be “0”. Therefore, a leakage current IL of a signal current IS flows to a left acoustic unit 77L for the left channel and a sound on the right channel is slightly emitted from the left acoustic unit 77L; as a result, so-called channel separation becomes worse.

On the other hand, as shown in FIG. 11B, in the case of the audio apparatus 60 of the second embodiment of the present invention, when the audio signal S11R was supplied from the audio signal source 63R only to the right channel, similarly to the case of the audio apparatus 80, a potential at the branch point P2 is not to be “0” by the effect of the impedance ZC on the ground wire 76C. Therefore, the leakage current IL of the signal current IS flows to the left acoustic unit 77L for the left channel.

However, in the audio apparatus 60, the signal waveform of an output audio signal S14L is corrected to adjust to the signal waveform of the original audio signal S11L by a distortion correcting circuit 70L for the left channel. Therefore, the leakage current IL of the signal current IS on the right channel is detected as a distortion component, and the output audio signal S14L in that the distortion component was added in the inverted phase can be supplied to the left acoustic unit 77L.

Thereby, in the audio apparatus 60, a leakage current component can be canceled out by the output audio signal S14L generated by the distortion correcting circuit 70L for the left channel. Therefore, when a sound on the left channel is transmitted from the left acoustic unit 77L, it can be prevented that a sound by the leakage current IL from the right channel is superimposed and supplied, and channel separation can be improved.

Further, in the audio apparatus 60, also with respect to a leakage current from the left channel to the right channel similarly to the leakage current IL from the right channel to the left channel, it can be similarly detected as a distortion component and can be corrected. Furthermore, mutual leakage currents can be detected as distortion components and can be corrected in the right channel and the left channel at the same time. Therefore, channel separation can be improved on the both channels of the left and the right.

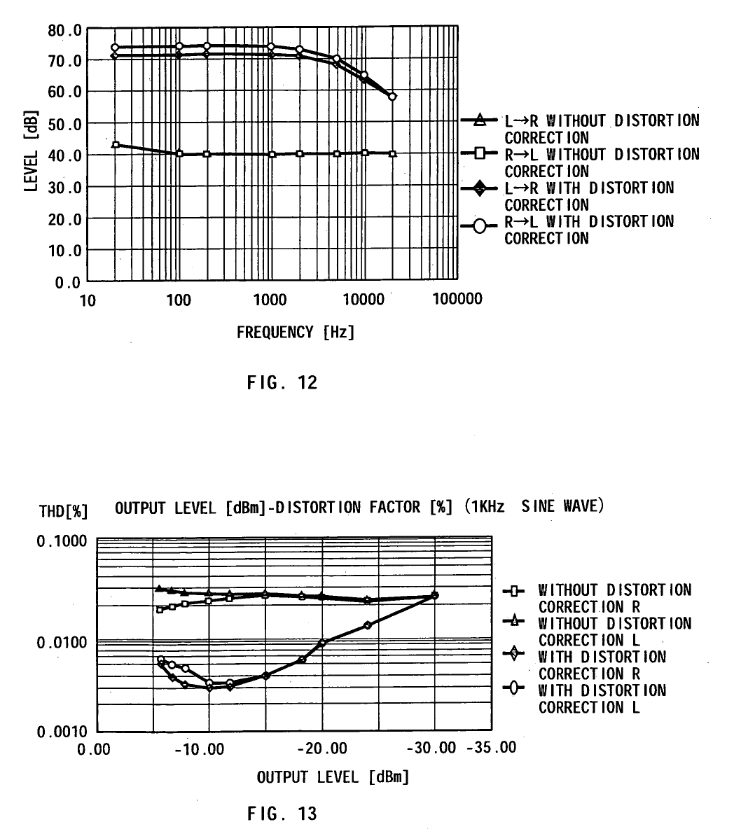

Here, the measurement results of the channel separation in the case of the audio apparatus 80 (without distortion correction) and the case of the audio apparatus 60 of the second embodiment of the present invention (with distortion correction) are shown in FIG. 12. Referring to FIG. 12, as to the both of the case from the right channel (R) to the left channel (L) and the case from the left channel (L) to the right channel (R), in the case with distortion correction, channel separation was improved approximately 30 dB in comparison with the case without distortion correction. It is shown that high quality sounds can be emitted from the right acoustic unit 77R and the left acoustic unit 77L (FIG. 10) respectively.

In this connection, referring to FIG. 12, in the case with distortion correction, a slight different was generated between the output level by the leakage current from the right channel (R) to the left channel (L) and the output level by the leakage current from the left channel (L) to the right channel (R). However, it is estimated that it was caused by measurement errors.

Next, the measurement results of distortion factor characteristics in the audio apparatus 80 (without distortion correction) and the audio apparatus 60 of the second embodiment of the present invention (with distortion correction) are shown in FIG. 13. Referring to this FIG. 13, in the case with distortion correction, the distortion factors were reduced on the both channels of the left and the right in comparison with the case without distortion correction. It is shown that the quality of sounds emitted from the right acoustic unit 77R and the left acoustic unit 77L (FIG. 10) were improved by the distortion correction.

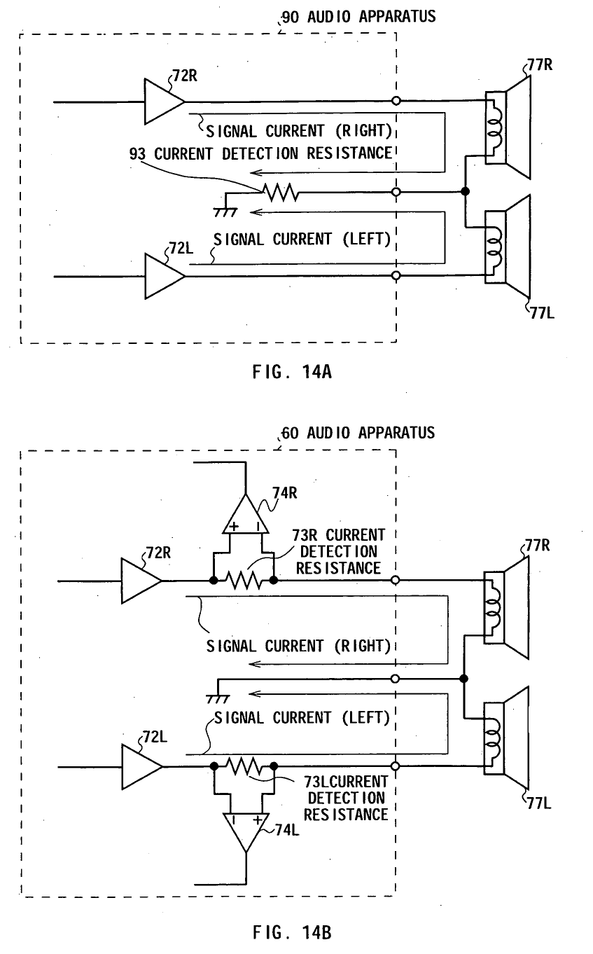

On the other hand, as an audio apparatus 90 shown in FIG. 14A, if a current detection resistance 93 is connected with a ground side used in common, signal currents on both channels of the left and the right flow to the current detection resistance 93. Therefore, the waveforms of the currents respectively flown to the left channel and the right channel cannot be separately detected. That is, a distortion component cannot be extracted with high accuracy, and the distortion component cannot be properly corrected.

On the contrary, as shown in FIG. 14B, in the audio apparatus 60 of the second embodiment of the present invention, the current detection resistances 73R and 73L are connected between the power amplifiers 72R and 72L and the right acoustic unit 77R and the left acoustic unit 77L respectively (that is, with the signal line side). Therefore, the waveforms of the currents respectively flown to the left channel and the right channel can be separately detected by the current detection resistances 73R and 73L, and each distortion component on the left channel and the right channel can be extracted with high accuracy, and the distortion component can be properly corrected.

According to the above configuration, in the distortion correcting circuits 70R and 70L in the audio apparatus 60 (FIG. 10), the current detection resistances 73R and 73L are provided between the power amplifiers 72R and 72L and the right acoustic unit 77R and the left acoustic unit 77L respectively. A distortion component on each channel of the left and the right is calculated by the current detection resistances 73R and 73L and the differential amplifiers 74R and 74L, and the distortion components are added to the original audio signals S11R and S11L respectively in the inverted phase. Thereby, the distortion components which were added to the audio signals S11R and S11L respectively in the inverted phase, and the distortion components in the output audio signals S14R and S14L that were caused by counter electromotive force generated in the voice coil 78R of the right acoustic unit 77R and the voice coil 78L of the left acoustic unit 77L and a leakage current from other channel are canceled out. Thus, the output audio signals S14R and S14L can be corrected to the signal waveforms equivalent to the original audio signals S11R and S11L. Thereby, channel separation of sounds to be emitted from the right acoustic unit 77R and the left acoustic unit 77L can be improved; thus, the sound quality can be improved.

### (3) Other Embodiments

In the aforementioned first embodiment, it has dealt with the case where the waveform of a current flown to the speaker 2 is detected by means of the current detection resistance 13 and the differential amplifier 14. However, the present invention is not only limited to this but also the waveform of a current flown to the speaker 2 may be detected by means of a solenoid coil for example. This is also similar as to the second embodiment.

Further, in the aforementioned second embodiment, it has dealt with the case where in the audio apparatus 60 having the two channels of the left and the right and using the ground wire 76C in common, distortion components on the both channels of the left and the right are extracted respectively, and the distortion components are corrected respectively. However, the present invention is not only limited to this but also, in an audio apparatus using a ground wire in common by an arbitrary number of channels such as an audio apparatus that has four channels to realize for example a surround system and uses a ground wire in common by the four channels, a distortion component on each channel may be extracted separately, and the distortion components may be corrected respectively.

Further, in the aforementioned first embodiment, it has dealt with the case where an output audio signal S4 is supplied to the conic speaker 2. However, the present invention is not only limited to this but also the output audio signal S4 may be supplied to a speaker having another system that has a voice coil such as a domed speaker, or speakers having various systems in that the current waveform of the supplied output audio signal S4 will be distorted.

Further, in the aforementioned first and second embodiments, it has dealt with the case where the present invention is applied to the audio apparatus 1 operating as an audio amplifier and the audio apparatus 60 being a portable CD player. However, the present invention is not only limited to this but also it may be applied to various electronic equipment having an audio signal amplifier circuit that amplifies an audio signal supplied from a predetermined audio signal source and supplies this to a speaker, headphones or the like, such as an audio circuit section built in a television receiving set, and an audio circuit section in a personal computer, a cellular phone or the like.

Further, in the aforementioned embodiments, it has dealt with the case where the audio apparatus 1 serving as an audio signal amplifying apparatus has the power amplifier 12 serving as an amplifier, the current detection resistance 13 and the differential amplifier 14 serving as a current detection section, the distortion component arithmetic unit 15 serving as a distortion component calculating section, and the distortion component adder 11 serving as a distortion component adding section. However, the present invention is not only limited to this but also an audio signal amplifying apparatus may have an amplifier, a current detection section, a distortion component calculating section and a distortion component adding section having other various circuit configurations.

According to an embodiment of the present invention, only a distortion component which was superimposed on an amplified audio signal by the effect of a speaker can be correctly calculated without receiving the effect of noise sneak, and the distortion component generated by the effect of the speaker and the distortion component added to the audio signal can be canceled out. Therefore, sounds faithfully according to the audio signal can be emitted from the speaker. Thus, an audio signal amplifying apparatus and a distortion correcting method in that the quality of sounds to be emitted from a speaker can be improved can be realized.

Furthermore, according to an embodiment of the present invention, only a distortion component which was superimposed on an amplified audio signal by the effect of a speaker and the effect from other channel via a ground wire can be correctly calculated, and the distortion component previously added to the audio signal and the distortion component generated by the effect of the speaker can be canceled out. Therefore, sounds faithfully according to the audio signal can be emitted from the speaker. Thus, an audio signal amplifying apparatus in that the quality of sounds to be emitted from a speaker can be improved can be realized.

While there has been described in connection with the preferred embodiments of the present invention, it will be obvious to those skilled in the art that various changes, modifications, combinations, sub-combinations and alternations may be aimed, therefore, to cover in the appended claims all such changes and modifications as fall within the true spirit and scope of the present invention.

The present invention can be also used in various electronic equipment having an audio signal amplifier circuit.

What is claimed is:

1. An audio signal amplifying apparatus comprising:
an amplifier for amplifying an audio signal and generating an amplified audio signal;
current detecting means provided between said amplifier and a speaker, for detecting a current waveform of said amplified audio signal on which a distortion component was superimposed by an effect of the speaker when said amplified audio signal was transmitted from the amplifier to the speaker;
distortion component calculating means for calculating said distortion component based on a difference between said current waveform and a signal waveform of said audio signal; and
distortion component adding means for supplying an added result by that said distortion component was added to said audio signal to said amplifier.

2. The audio signal amplifying apparatus according to claim 1, wherein
said current detecting means detects a current detection signal based on a potential difference at both ends of a non-inductive resistance that is connected in series between said amplifier and said speaker.

3. An audio signal amplifying apparatus for transmitting plural amplified audio signals by that audio signals on plural channels were amplified respectively, to a speaker of said each channel via a ground wire used in common by each of the channels respectively, the audio signal amplifying apparatus comprising:
an amplifier for amplifying said audio signal for every channel, and generating said amplified audio signal;
current detecting means provided between said amplifier and a speaker of each channel, for respectively detecting the current waveforms of the amplified audio signals on which a distortion component was superimposed by an effect of the speaker and an effect from other channel via said ground wire when said amplified audio signals were transmitted from the amplifier to the speaker;
distortion component calculating means for calculating said distortion component based on a difference between said current waveform and the signal waveform of said audio signal for every channel; and
distortion correcting means for supplying an added result by that said distortion component was added to said audio signal for every channel to said amplifier.

4. A distortion correcting method in an audio signal amplifying apparatus that amplifies an audio signal by an amplifier and transmits the amplified signal to a speaker, the distortion correcting method in an audio signal amplifying apparatus comprising:
the current detecting step of detecting the current waveform of said amplified audio signal on which a distortion component was superimposed by an effect of the speaker, before said audio signal that was amplified by said amplifier is supplied to said speaker;
the distortion component calculating step of calculating said distortion component based on a difference between said current waveform and the signal waveform of said audio signal; and
the distortion component adding step of supplying an added result by that said distortion component was added to said audio signal to said amplifier.
